(19) United States
(12) Patent Application Publication
(10) Pub. No.: US 2025/0227871 A1
(43) Pub. Date: Jul. 10, 2025

(54) POWER DISTRIBUTION SHELVING

(71) Applicant: Quality Electrical Systems, Inc., West Jordan, UT (US)

(72) Inventor: Kenneth DeWayne Worton, West Jordan, UT (US)

(21) Appl. No.: 19/011,553

(22) Filed: Jan. 6, 2025

Related U.S. Application Data
(63) Continuation of application No. 18/809,298, filed on Aug. 19, 2024.
Application No. 18/809,298 is a continuation of application No. 18/589,326, filed on Feb. 27, 2024, now abandoned.
Application No. 18/589,326 is a continuation of application No. 18/477,274, filed on Sep. 28, 2023, now abandoned.
Application No. 18/477,274 is a continuation of application No. 18/298,307, filed on Apr. 10, 2023, now abandoned.
Application No. 18/298,307 is a continuation of application No. 18/057,744, filed on Nov. 21, 2022, now abandoned.
Application No. 18/057,744 is a continuation of application No. 17/860,099, filed on Jul. 7, 2022, now abandoned.
Application No. 17/860,099 is a continuation of application No. 17/683,331, filed on Feb. 28, 2022, now abandoned.
Application No. 17/683,331 is a continuation of application No. 17/501,920, filed on Oct. 14, 2021, now abandoned.
Application No. 17/501,920 is a continuation of application No. 17/331,301, filed on May 26, 2021, now abandoned.
Application No. 17/331,301 is a continuation of application No. 17/146,324, filed on Jan. 11, 2021, now abandoned.
Application No. 17/146,324 is a continuation of application No. 17/000,304, filed on Aug. 22, 2020, now abandoned.

(51) Int. Cl. H05K 7/14; H02G 5/04; H02G 5/06

(52) U.S. Cl. CPC H05K 7/1492; H02G 5/04; H05K 7/1489; H02G 5/06

(57) ABSTRACT

A power distribution shelving assembly. The assembly includes a first and second support, and at least one shelf supported by the first and second supports. A bus bar may be secured to the at least one shelf. A main bus assembly may be electrically connected to the bus bar. The power connection may be configured to conduct at least 2000 amps of power and distribute at least 1000 amps to the bus bar secured to the at least one shelf.

### CROSS-REFERENCE TO RELATED APPLICATIONS

This application is a continuation of U.S. patent application Ser. No. 18/809,298, filed Aug. 19, 2024, which is a continuation of U.S. patent application Ser. No. 18/589,326, filed Feb. 27, 2024, which is a continuation of U.S. patent application Ser. No. 18/477,274, filed Sep. 28, 2023, which is a continuation of U.S. patent application Ser. No. 18/298,307, filed Apr. 10, 2023, which is a continuation of U.S. patent application Ser. No. 18/057,744, filed Nov. 21, 2022, which is a continuation of U.S. patent application Ser. No. 17/860,099, filed Jul. 7, 2022, which is a continuation of U.S. patent application Ser. No. 17/683,331, filed Feb. 28, 2022, which is a continuation of U.S. patent application Ser. No. 17/501,920, filed Oct. 14, 2021, which is a continuation of U.S. patent application Ser. No. 17/331,301, filed May 26, 2021, which is a continuation of U.S. patent application Ser. No. 17/146,324, filed Jan. 11, 2021, which is a continuation of U.S. patent application Ser. No. 17/000,304, filed Aug. 22, 2020, titled “POWER DISTRIBUTION SHELVING,” which are hereby incorporated by reference herein in their entirety, including but not limited to those portions that specifically appear hereinafter, the incorporation by reference being made with the following exception: In the event that any portion of the above-referenced applications is inconsistent with this application, this application supercedes said above-referenced applications.

### STATEMENT REGARDING FEDERALLY SPONSORED RESEARCH OR DEVELOPMENT

Not Applicable.

### BACKGROUND

### 1. The Field of the Present Disclosure

The present disclosure relates generally to a power distribution assembly, and more particularly, but not necessarily entirely, to a power distribution shelving unit configured to provide for increased power distributed along individual shelves along the unit.

### 2. Description of Related Art

Power distribution is a common issue in industrial, office and home settings. Electronics often need a hard wired power source, however, the primary power source is conventionally a simple wall outlet, which delivers 120 volts or 220 volts of power. If an electronic device must be hardwired to a wall outlet, then the electronic device must be positioned by or near the wall outlet, or a power cord must be run from the wall outlet to the electronic device.

With the rise in the power needs of various industries, including in the digital currency mining industry, the need for high powered servers has also increased. These mining servers can require significant power in order to operate and many Bit Coin mining operations utilize high numbers of servers simultaneously. This need to provide sufficient power to servers, like these, has created a problem of getting industrial power sources converted to useable power increments, at locations where servers can be positioned and utilized.

Despite the advantages of known server shelving and power strips, improvements are still being sought. The prior art is thus characterized by several disadvantages that are addressed by the present disclosure. The present disclosure minimizes, and in some aspects eliminates, the above-mentioned failures, and other problems, by utilizing the methods and structural features described herein.

The features and advantages of the present disclosure will be set forth in the description which follows, and in part will be apparent from the description, or may be learned by the practice of the present disclosure without undue experimentation. The features and advantages of the present disclosure may be realized and obtained by means of the instruments and combinations particularly pointed out in the appended claims. Any discussion of documents, acts, materials, devices, articles or the like which has been included in the present specification is not to be taken as an admission that any or all of these matters form part of the prior art base, or were common general knowledge in the field relevant to the present disclosure as it existed before the priority date of each claim of this application.

### BRIEF DESCRIPTION OF THE DRAWINGS

The features and advantages of the disclosure will become apparent from a consideration of the subsequent detailed description presented in connection with the accompanying drawings in which:

FIG. 1 is a perspective power distribution shelving unit in accordance with the principles of the present disclosure;

FIG. 2 is a perspective view of a partially disassembled a perspective power distribution shelving unit of FIG. 1;

FIG. 3 is a magnified view side of a portion of the partially disassembled a perspective power distribution shelving unit of FIG. 2;

FIG. 4 is a perspective view of a main buswork assembly in accordance with the principles of the present disclosure;

FIG. 5 is magnified perspective view of the main buswork assembly of FIG. 4;

FIG. 6 is a perspective view of a shelf assembly in accordance with the principles of the present disclosure;

FIG. 7 is an exploded view of the shelf assembly of FIG. 6;

FIG. 8 is a perspective view of a breaker assembly in accordance with the principles of the present disclosure; and

FIG. 9 is an exploded view of a component of the breaker assembly of FIG. 8.

### DETAILED DESCRIPTION

For the purposes of promoting an understanding of the principles in accordance with the disclosure, reference will now be made to the embodiments illustrated in the drawings and specific language will be used to describe the same. It will nevertheless be understood that no limitation of the scope of the disclosure is thereby intended. Any alterations and further modifications of the inventive features illustrated herein, and any additional applications of the principles of the disclosure as illustrated herein, which would normally occur to one skilled in the relevant art and having possession of this disclosure, are to be considered within the scope of the disclosure claimed.

It must be noted that, as used in this specification and the appended claims, the singular forms “a,” “an,” and “the” include plural referents unless the context clearly dictates otherwise.

In describing and claiming the present disclosure, the following terminology will be used in accordance with the definitions set out below.

As used herein, the terms “comprising,” “including,” “containing,” “characterized by,” and grammatical equivalents thereof are inclusive or open-ended terms that do not exclude additional, unrecited elements or method steps.

As used herein, the phrase “consisting of” and grammatical equivalents thereof exclude any element, step, or component not specified in the claim.

As used herein, the terms “bus,” “buswork,” “bus bar, which are used interchangeably, and grammatical equivalents thereof, are herein defined as a strip or bar configured to conduct or otherwise distribute current power. While these terms typically define a metallic element capable of conducting electricity, these terms, as used herein may also include any known material capable of conducting or otherwise distributing electricity.

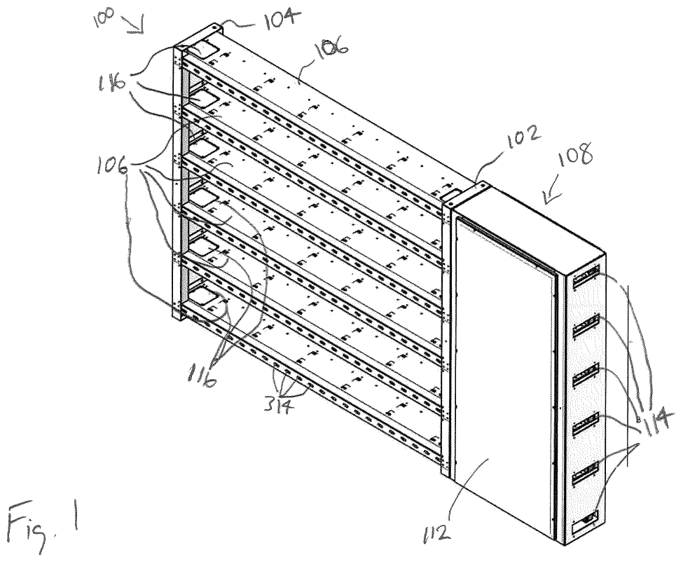

Referring to FIG. 1, the present invention includes a system and method that utilizes a power distribution shelving unit or assembly 100. The power distribution unit may include a first and second support 102 and 104 which may be connected to and support a plurality of identical or substantially identical shelves or shelving assemblies 106. Although the disclosed figures illustrate shelves 106 that are substantially identical, one of ordinary skill in the art will understand that shelves 106 need not be identical and may vary in both minor and significant ways and still fall within the scope of the invention. For example, any of disclosed shelves 106 may include all of the elements and components and disclosed below, of include fewer components, different components or simply include a platform to support an object or objects without any power distribution components or characteristics.

Each of the supports 102 and 104 may extend vertically, or substantially vertically, from a supporting foundation (not shown), although the supports 102 and 104 may also extend at any desired angle from a supporting foundation and supports 102 and 104 may be parallel or substantially parallel with one another, or alternatively, extend at converging or diverging angles with one another.

Each of the shelves 106 may extend horizontally, or substantially horizontally, the supports 102 and 104, but may also extend at any desired angle from the supports 102 and 104. Adjacent shelves may be parallel or substantially parallel with one another, or alternatively, may extend at converging or diverging angles with one another.

Each self 106 may be secured or connected to the supports 102 and 104 using removable fasteners, fixed fasteners, or other known faster or attachment mechanism. Alternatively, each shelf 106 may be formed as a single unitary piece with the supports 102 and 104.

The power distribution shelving unit 100 may also include a power source housing 108. The power source housing 108 may be hollow and may partially or fully enclose a main power source buswork assembly 110, or main bus assembly. The power source housing 108 may include side walls, with at least one sidewall 112 being removable to allow access within the power source housing 108.

The power source housing 108 may also include a plurality of slots or openings 114, which may provide access for power cords, wiring, or other desired utilities. The power source housing 108 and buswork assembly 110 may be configured to receive 6000 amps, or 4000-8000 amps, or more, of power and distribute 1000 amps, or 500 amps to 1500 amps, or more of power along each of the shelves 106.

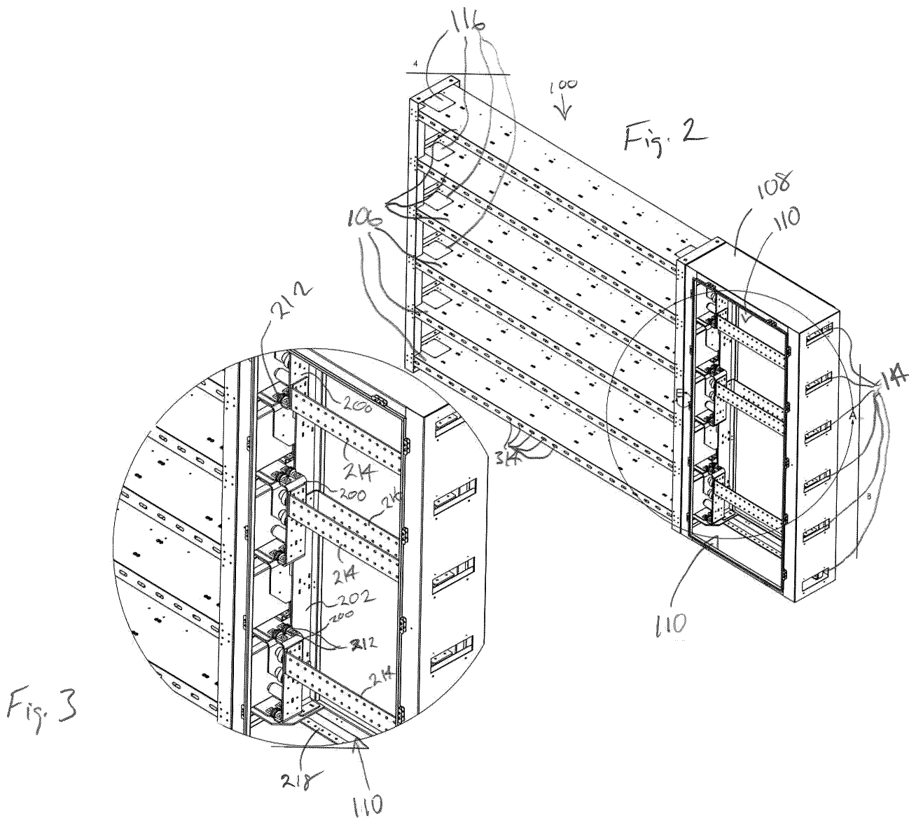

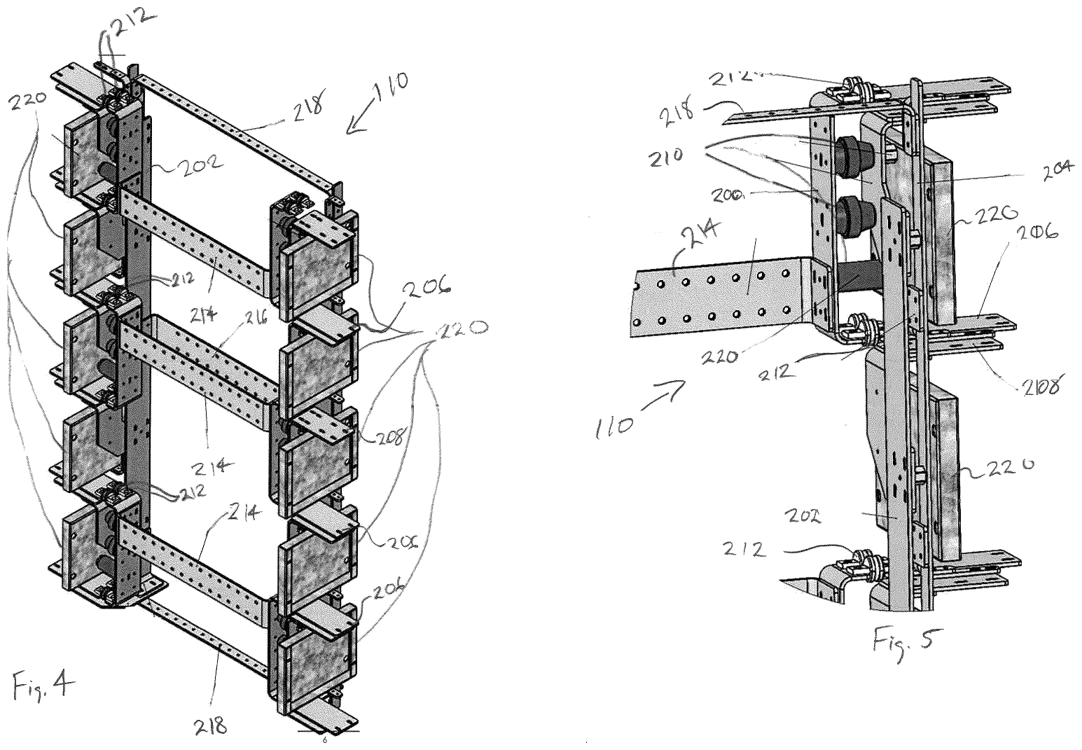

Referring to FIGS. 2-5, the main power source buswork assembly 110 may include a main hot bus 200, a main neutral bus 202 and a main ground bus 204, and each of these main bus components 200, 202, and 204 may be configured to receives power from an external source and distribute such power through to each of the shelves 106 as disclosed in more detail below.

The main hot bus 200 may be electrically connected to a hot splice 206 and main neutral bus 204 may be electrically connected to a neutral splice 206. The hot and neutral splices 206 and 208 may be configured to connect to an external power source (not shown) and distribute such power to the main bus components 200 and 202. The hot and neutral splices 204 and 206 may also be used to splice or electrically connect multiple power distribution units 100 to one another via corresponding connection to splicing panels 116, or neutral bus connections, integrated with, or otherwise connected to shelves 106. This connection of multiple power distribution shelving units 100 can enable a user to customize power distribution based on power needs, including number of power consuming devices or the amount of power needed per device.

The main power source buswork assembly 110 may also include a plurality of insulators 210 to achieve and maintain distance between electrical buswork components such as the main hot bus 200 and the main neutral bus 202. Fuses 212 may also be integrated and electrically connected to the main hot bus 200 and hot splice 206 as a safety mechanism in case of a power surge, such that the fusees 212 can break the corresponding circuit and impede the transfer of power.

The main power source buswork assembly 110 may also include a hot bus connection 214 electrically connecting corresponding main hot buses 200, a neutral bus connection 216 electrically connecting main neutral buses 202, and a ground bridge 218 electrically connecting main ground buses 204. The hot bus connection 214, neutral bus connection 216, and ground bridges 218 are configured to transfer power between external power sources or electrically connected power distribution shelving units 100, to corresponding main hot, neutral, and ground buses.

Each main power source buswork assembly 110 may also include a plurality of back panels 220. These back panels may be configured to be secured or fixed to the power source housing 108 such that the main power source buswork 110 may be protected from external elements and users or bystanders may be protect from the hot electrical components within the power source housing.

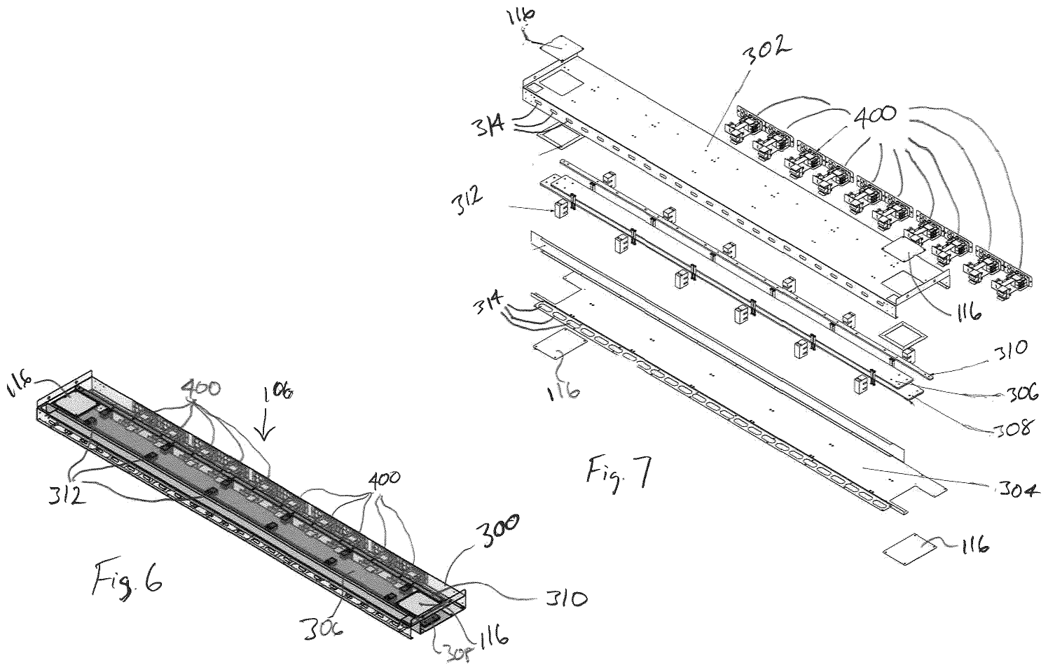

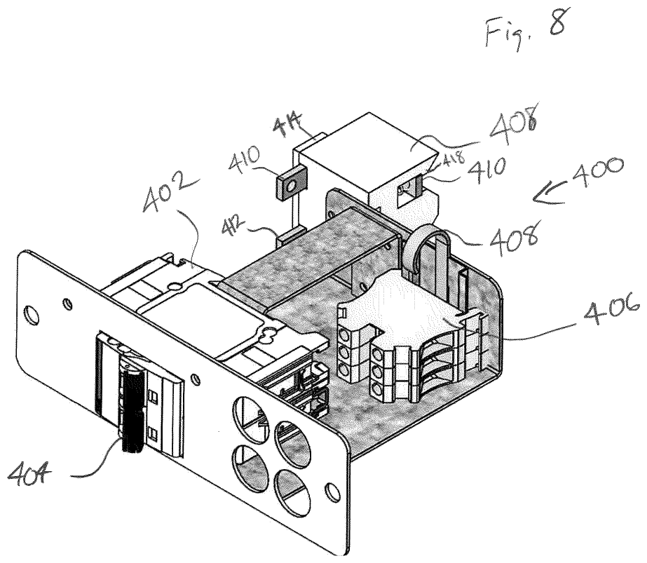

Referring now to FIGS. 6 and 7, each shelf assembly 106 may include a shelf housing 300 having top panel 302 and a bottom panel 304 which can be removably secured to one another to form a hollow or substantially hollow interior. Each of the top and bottom panels 302 and 304 include corresponding splicing panels 116.

Within interior of the shelf housing 300 are integrated shelf buswork, or bus bar. This shelf buswork may include a bus bar which may have a hot bus 306, neutral bus 308 and a ground bus 310. The hot bus 306, neutral bus 308 and ground bus 310 may be electrically connected to the corresponding main hot bus 200, main neutral bus 204 and main ground bus 206, which can the facilitate providing power along each shelf 106. The bus bar, including the hot bus 306, neutral bus 308, and ground bus 310 may extend the entirety of the shelf 106, as shown in FIG. 6, or the substantial entirety, majority, or partial length of the shelf 106.

The hot bus 306, neutral bus 308, and ground bus 310 maintain a safe and operable distance from one another via engagement with corresponding spacers 312, or insulators. These spacer can be made and manufactured from any desired electrically insulating material that with also maintain its shape while holding the corresponding hot bus 306, neutral bus 308, and ground bus 310 in place with respect to one another.

Each shelf 106 may also include a plurality of circuit breaker assemblies 400. Each circuit breaker assembly 400 may be inserted into the shelf housing 300 via a corresponding opening in the shelf housing 300. The circuit breaker assembly 400 can then be electrically connected to the hot bus 310 within the shelf housing 300, whereby providing power to a corresponding circuit, device, wiring, outlet, or other desired electrical system. The circuit breaker assemblies 400 can enable a layman or novice electrician to easily remove replace or otherwise customize the configuring of power distribution to power consuming devices, which maintaining adequate safety against power surges anywhere throughout the power distribution shelving unit 100.

The circuit breaker assemblies 400 may be 20 amp circuit breakers, enabling the transfer of power sufficient for 20 amp circuits. Alternative circuit breaker assemblies may also be used of any desired power rating, adequate to maintain safety in case of a power surge. Additionally, each circuit breaker assembly 400 need not be of the same power rating and thus customizable by a user, depending on the power needs of corresponding power consuming devices.

Each circuit breaker assembly may also include a mechanism to transfer power through to a power consuming device (not shown), such as a hardwired connection, electrical outlet, or other desired electrical connection. This electrical connection may be accessible through a plurality of openings 314 in the top and bottom panels 302 and 304 of the shelf housing 300, opposite the openings that receive the corresponding circuit breaker assemblies 400.

Referring to FIGS. 6-8, each circuit breaker assembly 400 may include a breaker 402 having a corresponding breaker switch 404 which can be used to shut off the power transferred through the circuit breaker assembly 400, or reset a tripped circuit breaker assembly 400 after a power surge has been detected and the corresponding circuit it broken.

Each circuit breaker assembly 400 may also include terminal 406. The terminal 406 may be configured to transfer power through to a power consuming device (not shown) via an electrical conduit, such as a hardwired connection, electrical outlet, or other desired electrical connection. As described above, the circuit breaker assembly 400 with the corresponding and integrated electrical connection, can be customized by a user interchangeably with other alternative circuit breaker assemblies and or electrical connections in order to meet the power consumption need of a user, electrical system or electrical device.

Each circuit breaker assembly may also include ground tab 408 which can make contact with the ground bus 310, grounding the corresponding electrical connection. The ground tab 408 may have a curved end portion that can provide an outward spring bias force that may be compressed as the circuit breaker assembly 400 is inserted into the shelf housing 300 and into connection with the ground bus 310, thus ensuring constant electrical connection between the ground tab 408 and the ground bus 310.

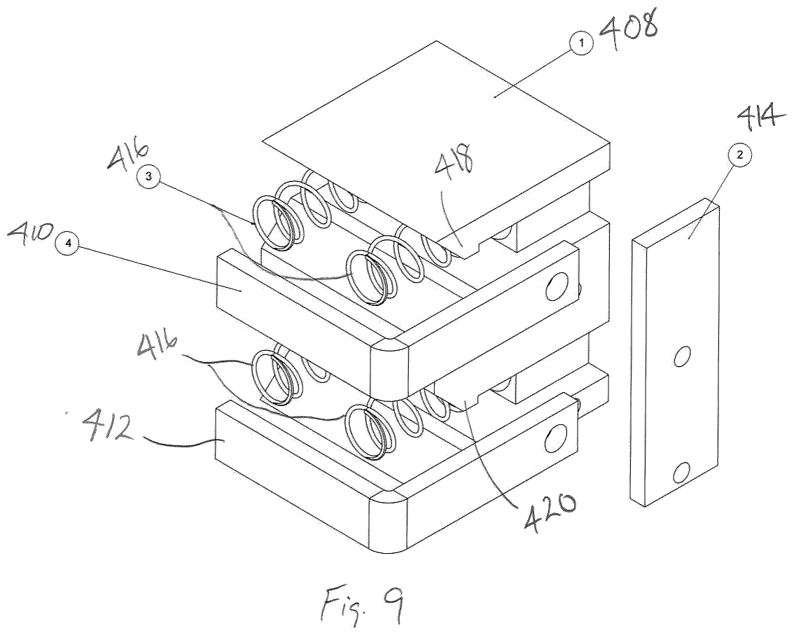

Referring to FIGS. 8 and 9, each circuit breaker assembly 400 may include a bus connector 408. The bus connector 408 may include a hot bus tab 410 and a neutral bus tab 412, each configured to make and maintain electrical contact with the corresponding hot bus 306 and neutral bus 308, thereby transferring power from the hot bus 306 through the circuit breaker assembly 400. Each of the hot bus tab 410 and the neutral bus tab 412 are mounted to the bus connector via a mounting bracket 414.

The bus connector 408 also includes a plurality of springs 416 that are mounted within the bus connecter 408 but extend outwardly against the corresponding hot bus tab 410 and neutral bus tab 412, which biases the hot bus tab 410 and neutral bus tab 412 against the corresponding hot bus 306 and neutral bus 308 when the circuit breaker assembly 400 is inserted into the shelf housing 300 and into electrical engagement with the hot bus 306 and neutral bus 308.

Further, the bus connector 408 may include retention tabs 418 and 420 which may be configured to bias against the corresponding hot bus 306 and neutral bus 308 to maintain sufficient electrical connection between the hot bus tab 410 and the hot bus 306 and the neutral bus tab 412 and the neutral bus 308, while still enabling a user to pull out the circuit breaker assembly 400 from the shelf housing 300 without damaging the hot bus 306 or the neutral bus 308, enabling easy replacement or installation of the circuit breaker assemblies 400.

It will be appreciated that the structure and apparatus disclosed herein is merely one example of a means for providing a power distribution shelving unit, and it should be appreciated that any structure, apparatus or system for distributing power which performs functions the same as, or equivalent to, those disclosed herein are intended to fall within the scope of a means for distributing power, including those structures, apparatus or systems for distributing power which are presently known, or which may become available in the future. Anything which functions the same as, or equivalently to, a means for distributing power falls within the scope of this element.

Those having ordinary skill in the relevant art will appreciate the advantages provided by the features of the present disclosure.

In the foregoing Detailed Description, various features of the present disclosure are grouped together in a single embodiment for the purpose of streamlining the disclosure. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment. Thus, the following claims are hereby incorporated into this Detailed Description of the Disclosure by this reference, with each claim standing on its own as a separate embodiment of the present disclosure.

It is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been shown in the drawings and described above with particularity and detail, it will be apparent to those of ordinary skill in the art that numerous modifications, including, but not limited to, variations in size, materials, shape, form, function and manner of operation, assembly and use may be made without departing from the principles and concepts set forth herein.

1. A power distribution shelving unit, comprising:
a first and second support;
at least one shelf supported by the first and second supports;
a bus bar secured to the at least one shelf and extending along a length of the at least one shelf; and
a main bus assembly electrically connected to the bus bar, wherein the main bus assembly is configured to conduct at least 2000 amps of power and distribute at least 1000 amps to the bus bar secured to the at least one shelf.

2. The power distribution shelving unit of claim 1, further comprising:
a power source housing secured to the first support, wherein the power source housing encloses the main bus assembly.

3. The power distribution shelving unit of claim 1, further comprising:
a plurality of shelves supported by the first and second supports.

4. The power distribution shelving unit of claim 3, comprising:
a bus bar secured to each of the plurality of shelves and extending along at least a majority length of each of the plurality of shelves, and
wherein each of the bus bars are electrically connected to the main bus assembly.

5. The power distribution shelving unit of claim 1, comprising:
at least one circuit breaker assembly removably connected to the at least one shelf and the bus bar.

6. The power distribution shelving unit of claim 1, comprising:
a plurality of circuit breaker assemblies removably connected to the at least one shelf and the bus bar.

7. The power distribution shelving unit of claim 4, wherein the main bus assembly is configured to conduct at least 6000 amps of power and distribute at least 1000 amps of power to each of the bus bars of each the plurality of shelves.

8. The power distribution shelving unit of claim 1, comprising:
at least one splicing panel configured to electrical connect and distribute power to a second power distribution shelving unit.

9. The power distribution shelving unit of claim 5, wherein the at least one shelf includes a hollow shelf housing, wherein the shelf housing encloses at least a portion of the bus bar and at least a portion of the at least one circuit breaker assembly.

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. A power distribution shelving unit, comprising:
a first and second support;
at least one shelf supported by the first and second supports, wherein the at least one shelf includes a hollow shelf housing;
a bus bar secured to the at least one shelf within the shelf housing,
at least one circuit breaker removably connected to the bus bar within the shelf housing; and
a main bus assembly electrically connected to the bus bar, wherein the main bus assembly is configured to conduct and distribute power from a power source outside of the power distribution shelving unit.

31. The power distribution shelving unit of claim 30, wherein the main bus assembly is configured to conduct at least 2000 amps of power and distribute at least 1000 amps to the bus bar secured to the at least one shelf.

32. The power distribution shelving unit of claim 30, further comprising:
a power source housing secured to the first support, wherein the power source housing encloses the main bus assembly.

33. The power distribution shelving unit of claim 30, further comprising:
a plurality of shelves supported by the first and second supports.

34. The power distribution shelving unit of claim 33, comprising:
a bus bar secured to each of the plurality of shelves and extending along at least a majority length of each of the plurality of shelves, and
wherein each of the bus bars are electrically connected to the main bus assembly.

35. The power distribution shelving unit of claim 34, comprising:
at least one circuit breaker assembly removably connected to each of the bus bars of the plurality of shelves.

36. The power distribution shelving unit of claim 30, wherein the main bus assembly is configured to conduct at least 6000 amps of power and distribute at least 1000 amps of power to each of the bus bars of each the plurality of shelves.

37. The power distribution shelving unit of claim 30, comprising:
at least one splicing panel configured to electrical connect and distribute power to a second power distribution shelving unit.

38. The power distribution shelving unit of claim 34, wherein each of the plurality of shelves includes a hollow shelf housing, wherein each shelf housing encloses at least a portion of the bus bar and at least a portion of the at least one circuit breaker assembly.

39. The power distribution shelving unit of claim 30, where the bus bar is secured along at least a majority length of the at least one shelf.

40. A power distribution shelving unit, comprising:
a first and second support;
a plurality of shelves supported by the first and second supports, wherein each of the plurality of shelves includes a hollow shelf housing;
a bus bar secured to and extending an entire length of each of the plurality of shelves within the shelf housing,
a plurality of circuit breaker assemblies removably connected to each bus bar within each shelf housing;
a main bus assembly electrically connected each of the bus bars, wherein the main bus assembly is configured to conduct and distribute power from a power source outside of the power distribution shelving unit, and wherein the main bus assembly is configured to conduct at least 6000 amps of power and distribute at least 1000 amps of power to each of the bus bars of each the plurality of shelves;
a power source housing secured to the first support, wherein the power source housing encloses the main bus assembly; and
at least one splicing panel configured to electrical connect and distribute power to a second power distribution shelving unit.
